(19) United States
(12) Patent Application Publication
(10) Pub. No.: US 2026/0192580 A1
(43) Pub. Date: Jul. 9, 2026

(54) HIGH-PRECISION SIX-DEGREE-OF-FREEDOM MICROPOSITIONER FOR FINE ADJUSTMENT OF OLED SUBSTRATE

(71) Applicant: JI HUA LABORATORY, Foshan (CN)

(72) Inventors: Yunlong ZHU, Foshan (CN); Zhi ZHOU, Foshan (CN); Qi LI, Foshan (CN); Guanming WANG, Foshan (CN); Shuhui WANG, Foshan (CN)

(21) Appl. No.: 18/730,242

(22) PCT Filed: Apr. 23, 2023
(86) PCT No.: PCT/CN2023/090079

§ 371 Date: Jul. 18, 2024

(30) Foreign Application Priority Data
Feb. 6, 2023 (CN) 202310066069.3

(51) Int. Cl. B41J 11/14; B41J 3/28; B41J 3/407; B41J 11/00; B41J 11/06; B41J 29/377; H10K 71/13

(52) U.S. Cl. CPC B41J 11/14; B41J 3/28; B41J 3/407; B41J 11/0095; B41J 11/06; B41J 29/377; H10K 71/135

(57) ABSTRACT

A high-precision six-degree-of-freedom micropositioner for fine adjustment of an OLED substrate is disclosed. The high-precision six-degree-of-freedom micropositioner includes a sealed case, a gas purifier and an inkjet printing device and a six-degree-of-freedom motion platform. The sealed case is provided with a return air passage communicating with a return air inlet and a return air outlet. The sealed case is provided with a fan unit configured to drive an air flow in the sealed case to flow from the return air inlet to the return air outlet. The sealed case is provided with a filter screen and a flow-stabilizing plate arranged sequentially along a flow direction of gas in the sealed case, and the six-degree-of-freedom motion platform is located on a side of the flow-stabilizing plate away from the filter screen.

### CROSS-REFERENCE TO RELATED APPLICATIONS

The present application is the national phase under 35 U.S.C. § 371 of PCT international application No. PCT/CN2023/090079, which has an international filing date of Apr. 23, 2023 and claims priority to Chinese patent application No. 202310066069.3, filed on Feb. 6, 2023, and entitled “HIGH-PRECISION SIX-DEGREE-OF-FREEDOM MICROPOSITIONER FOR FINE ADJUSTMENT OF OLED SUBSTRATE”. The contents of the above identified PCT international application and Chinese patent application are incorporated herein in their entireties by reference for all purposes.

### TECHNICAL FIELD

The present disclosure relates to the field of display panel processing technologies, and in particular, to a high-precision six-degree-of-freedom micropositioner for fine adjustment of an OLED substrate.

### BACKGROUND

With the development of display technology, display panels are gradually becoming larger in size. Traditional liquid crystal display (LCD) has the characteristics of high manufacturing cost, while organic light-emitting diode (OLED) has the characteristics of low power consumption, rich colors, and large field of view, so the popularity of OLED is increasing. Inkjet printing (IJP) is a non-contact micron-level printing technology that does not require a mask plate. An inkjet head directly ejects nano-sized solutions on flexible or hard substrates. This technology has the characteristics of low cost. When large-sized objects such as OLED are processed using inkjet printing technology, an OLED to-be-processed substrate can be placed on a six-degree-of-freedom micro-positioning platform, and the six-degree-of-freedom micro-positioning platform can adjust a position of the OLED substrate relative to the inkjet head. However, in an actual inkjet printing process, there is still a problem of insufficient printing accuracy.

### SUMMARY

According to various embodiments of the present disclosure, a high-precision six-degree-of-freedom micropositioner for fine adjustment of an OLED substrate is provided.

A technical solution is as follows.

A high-precision six-degree-of-freedom micropositioner for fine adjustment of an OLED substrate is provided, the high-precision six-degree-of-freedom micropositioner including:
an inkjet printing device;
a six-degree-of-freedom motion platform, the six-degree-of-freedom motion platform having a placement position for placing a to-be-processed substrate;
a sealed case, the inkjet printing device and the six-degree-of-freedom motion platform being both located in the sealed case, and an inkjet head of the inkjet printing device being configured to eject solution onto the to-be-processed substrate placed at the placement position, and the six-degree-of-freedom motion platform being configured to adjust a relative position between the placement position and the inkjet head,
the sealed case being provided with a return air inlet and a return air outlet, a return air passage communicating with the return air inlet and the return air outlet being arranged outside the sealed case, a fan unit being arranged inside the sealed case, the fan unit being configured to drive air flow in the sealed case to flow from the return air inlet to the return air outlet, a filter screen and a flow-stabilizing plate being sequentially arranged inside the sealed case along a flow direction of gas in the sealed case, and the six-degree-of-freedom motion platform being located on a side of the flow-stabilizing plate away from the filter screen; and
a gas purifier having an exhaust port communicating with the sealed case.

In an embodiment, a periphery of the flow-stabilizing plate is connected to the sealed case. A space inside the sealed case is divided into an inkjet space layer and an auxiliary space layer. The six-degree-of-freedom motion platform and the inkjet printing device are both located in the inkjet space layer. The filter screen is located in the auxiliary space layer. The filter screen is arranged in parallel with and spaced from the flow-stabilizing plate. The fan unit includes a plurality of fans. Geometric centers of the plurality of fans are evenly spaced on a virtual mounting plane. The virtual mounting plane is arranged in parallel with and spaced from the filter screen and located on a side of the filter screen away from the flow-stabilizing plate. The return air inlet is formed in a part of the sealed case that encloses the auxiliary space layer, and the return air outlet is formed in a part of the sealed case that encloses the inkjet space layer.

In an embodiment, the high-precision six-degree-of-freedom micropositioner includes a plurality of the return air passages. The sealed case is provided with a plurality of pairs of the return air inlet and the return air outlet. Each pair of the return air inlet and the return air outlet corresponds to one of the plurality of return air passages.

In an embodiment, a position on the sealed case where the sealed case communicates with a gas purifier is located on an air inlet side of the fan unit. A position on the sealed case where the return air inlet is formed is located on the air inlet side of the fan unit.

In an embodiment, the six-degree-of-freedom motion platform includes a six-degree-of-freedom adjustment unit and a substrate placement table. The placement position is arranged on the substrate placement table, and the six-degree-of-freedom adjustment unit is configured to adjust the substrate placement table to move in an X-direction, to move in a Y-direction, to move in a Z-direction, to rotate around an X-axis, to rotate around a Y-axis, or to rotate around Z-axis relative to the inkjet head.

Two position detection units are arranged inside the sealed case, each position detection unit includes at least two laser probes, and each laser probe is configured to emit laser toward the substrate placement table. The at least two laser probes of one of the two position detection units are spaced sequentially along the X-direction, and the at least two laser probes of the other of the two position detection units are spaced sequentially along the Y-direction.

In an embodiment, the six-degree-of-freedom motion platform includes a substrate placement table, an upper fine-adjustment layer, a middle mounting base, a lower fine-adjustment layer and a bottom mounting base. The middle mounting base is arranged between the substrate placement table and the bottom mounting base and spaced from the substrate placement table and the bottom mounting base.

The lower fine-adjustment layer acts between the bottom mounting base and the middle mounting base to adjust the middle mounting base to move in an X-direction, to move in a Y-direction, or to rotate around a Z-axis relative to the bottom mounting base.

The upper fine-adjustment layer acts between the middle mounting base and the substrate placement table to adjust the substrate placement table to rotate around an X-axis, to rotate around a Y-axis, and to move in a Z-direction relative to the middle mounting base.

The placement position is arranged on the substrate placement table, and the bottom mounting base is arranged corresponding to the inkjet head, so that the inkjet head ejects solution onto the to-be-processed substrate placed at the placement position.

In an embodiment, the upper fine-adjustment layer includes a plurality of upper driving members and a gravity balancing unit, all of the upper driving members act between the middle mounting base and the substrate placement table, and have driving directions in the Z-direction, and the gravity balancing unit is supported between the middle mounting base and the substrate placement table.

In an embodiment, the gravity balancing unit includes a plurality of gravity balancing airbags, each gravity balancing airbag is supported between the middle mounting base and the substrate placement table, the plurality of gravity balancing airbags and the plurality of upper driving members are evenly spaced around the Z-axis, and at least one gravity balancing airbag is arranged between every two adjacent upper driving members in the direction around the Z-axis.

In an embodiment, the upper fine-adjustment layer further includes an air bearing. The upper driving member includes a first voice coil motor. A coil of the first voice coil motor is connected to the middle mounting base. A magnet of the first voice coil motor is connected to the substrate placement table. One of an air bearing shaft and a rotating ring of the air bearing is connected to the substrate placement table, and the other of the air bearing shaft and the rotating ring is connected to the middle mounting base.

Each upper driving member is provided with a detection optical grating configured to detect a motion distance of a mover of the corresponding upper driving member.

In an embodiment, the lower fine-adjustment layer includes a flexure spring and two lower driving units. One of the two lower driving units has a driving direction in the X-direction. The other of the two lower driving units has a driving direction in the Y-direction. The two lower driving units and the flexure spring both act between the bottom mounting base and the middle mounting base. The flexure spring is deformable so as to move in the X-direction, move in the Y-direction, or rotate around the Z-axis.

In an embodiment, the flexure spring includes a spring-mounting bottom base, a spring-mounting top base, a spring-mounting middle base, a flexible-around-Z-axis spring leaf, two first flexure spring leaves, and two second flexure spring leaves. The spring-mounting bottom base is mounted on the bottom mounting base. The flexible-around-Z-axis spring leaf is connected between the middle mounting base and the spring-mounting top base. The spring-mounting middle base is arranged between the spring-mounting bottom base and the spring-mounting top base and spaced from the spring-mounting bottom base and the spring-mounting top base. Each first flexure spring leaf is connected between the spring-mounting top base and the spring-mounting middle base. Each second flexure spring leaf is connected between the spring-mounting middle base and the spring-mounting bottom base. The two first flexure spring leaves are arranged on opposite sides of the spring-mounting middle base. The two second flexure spring leaves are arranged on another set of opposite sides of the spring-mounting middle base.

In an embodiment, each lower driving unit includes two lower driving members. Each of the two lower driving members of one of the two lower driving units has a driving direction in the X-direction, and each of the two lower driving members of the other of the two lower driving units has a driving direction in the Y-direction. Four lower driving members are evenly spaced around the flexure spring. The two lower driving members of one of the two lower driving units are staggered with the two lower driving members of the other of the two lower driving units in a direction around the flexure spring.

In an embodiment, each lower driving member is provided with a detection optical grating configured to detect a motion distance of a mover of the corresponding lower driving member.

The lower driving member includes a second voice coil motor.

In an embodiment, the high-precision six-degree-of-freedom micropositioner further includes a base and a supporting platform, both of which are located in the sealed case. The supporting platform is arranged on the base. A shock-absorbing unit is arranged between the supporting platform and the base. The six-degree-of-freedom motion platform is arranged on the supporting platform. The inkjet printing device is arranged on the supporting platform.

In an embodiment, the six-degree-of-freedom motion platform is slidably arranged on the supporting platform, and a direction in which the six-degree-of-freedom motion platform is slidable relative to the supporting platform is a Y-direction.

The supporting platform is provided with an X-axis guide rail spanning over a sliding path of the six-degree-of-freedom motion platform, and the inkjet printing device is slidably engaged on the X-axis guide rail.

### BRIEF DESCRIPTION OF THE DRAWINGS

In order to describe the technical solutions in the embodiments of the present application or the conventional technology more clearly, the following will briefly introduce the accompanying drawings required for describing the embodiments or the conventional technology. Apparently, the accompanying drawings in the following description are merely embodiments of the present disclosure, and for a person of ordinary skill in the art, other drawings can be obtained based on the disclosed drawings without creative efforts.

FIG. 1 is a schematic diagram illustrating a configuration of a high-precision six-degree-of-freedom micropositioner for fine adjustment of an OLED substrate according to an embodiment of the present disclosure.

FIG. 2 is a section diagram illustrating a part of the high-precision six-degree-of-freedom micropositioner shown in FIG. 1.

FIG. 3 is a schematic diagram illustrating a combination of a base, a supporting platform, a six-degree-of-freedom motion platform and an inkjet printing device.

FIG. 4 is a top view of the inkjet printing device shown in FIG. 3.

FIG. 5 is a schematic diagram illustrating a comparison between states of a to-be-processed substrate before and after fine adjustment.

FIG. 6 is a schematic diagram illustrating a configuration of a six-degree-of-freedom motion platform in the embodiment.

FIG. 7 is a schematic diagram illustrating a configuration of the six-degree-of-freedom motion platform with a substrate placement table is hidden.

FIG. 8 is a top view of the configuration shown in FIG. 7.

FIG. 9 is a schematic diagram illustrating a configuration of an air bearing in the embodiment.

FIG. 10 is an exploded view of the air bearing shown in FIG. 9.

FIG. 11 is a cross-sectional view of the air bearing shown in FIG. 9.

FIG. 12 is a partial enlarged view of a portion indicated by A in FIG. 11.

FIG. 13 is a schematic diagram illustrating a configuration of a combination of a bottom mounting base and a lower fine-adjustment layer in the embodiment.

FIG. 14 is a schematic diagram illustrating a configuration of a flexure spring in the embodiment.

FIG. 15 is an exploded view of the flexure spring shown in FIG. 14.

### DESCRIPTION OF REFERENCE NUMERALS

10, high-precision six-degree-of-freedom micropositioner for fine adjustment of an OLED substrate; 11, inkjet printing device; 12, sealed case; 121, return air passage; 122, inkjet space layer; 123, auxiliary space layer; 13, gas purifier; 14, fan unit; 141, fan; 15, filter screen; 16, flow-stabilizing plate; 17, base; 18, supporting platform; 181, position detection unit; 1811; laser probe 19, shock-absorbing unit; 20, six-degree-of-freedom motion platform; 21, substrate placement table; 211, placement position; 22, upper fine-adjustment layer; 221, upper driving member; 222, gravity balancing unit; 2221, gravity balancing airbag; 223, air bearing; 2231, air bearing shaft; 2232, rotating ring; 2233, air hole; 2234, air film; 23, middle mounting base; 24, lower fine-adjustment layer; 241, lower driving unit; 2411, lower driving member; 242, flexure spring; 2421, spring-mounting bottom base; 2422, spring-mounting top base; 2423, spring-mounting middle base; 2424, flexible-around-Z-axis spring leaf; 2425, first flexure spring leaf; 2426, second flexure spring leaf; 25, bottom mounting base; 26, detection optical grating; 30, to-be-processed substrate; 31, ink fountain.

### DETAILED DESCRIPTION OF THE EMBODIMENTS

The technical solutions in the embodiments of the present disclosure will be clearly and completely described with reference to the accompanying drawings. Apparently, the described embodiments are only some but not all of the embodiments of the present disclosure. Based on the embodiments of the present disclosure, all other embodiments obtained by a person of ordinary skill in the art without creative efforts shall fall within the protection scope of the present disclosure.

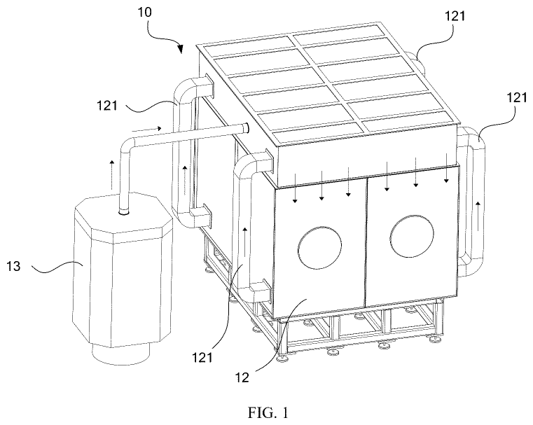

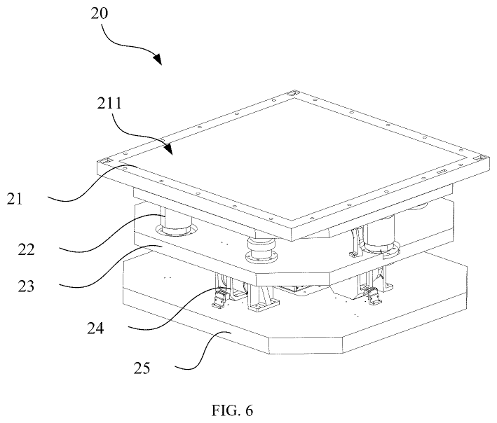

As shown in FIG. 1 to FIG. 4, in some embodiments of the present disclosure, a high-precision six-degree-of-freedom micropositioner 10 for fine adjustment of an OLED substrate is provided. The high-precision six-degree-of-freedom micropositioner 10 includes an inkjet printing device 11 and a six-degree-of-freedom motion platform 20. As shown in FIG. 6, the six-degree-of-freedom motion platform 20 has a placement position 211 for placing a to-be-processed substrate 30. An inkjet head of the inkjet printing device 11 is configured to eject solution onto the to-be-processed substrate 30 placed at the placement position 211, and the six-degree-of-freedom motion platform 20 is configured to adjust a relative position between the placement position 211 and the inkjet head.

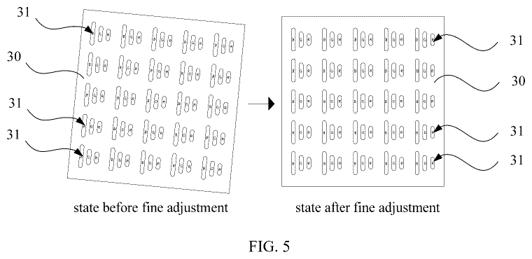

As shown in FIG. 5, when the to-be-processed substrate 30 is just placed at the placement position 211, ink fountains 31 on the to-be-processed substrate 30 may be tilted relative to the inkjet head. The six-degree-of-freedom motion platform 20 can be fine adjusted to position the to-be-processed substrate 30 correctly. The high-precision six-degree-of-freedom micropositioner 10 can be used to process large-sized panels such as OLED substrates.

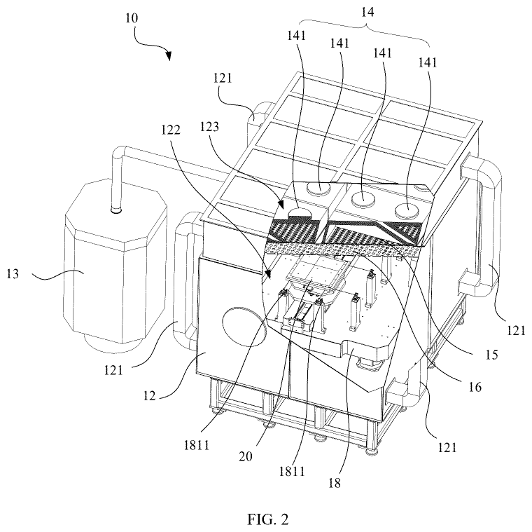

Further, as shown in FIG. 1 and FIG. 2, in some embodiments, the high-precision six-degree-of-freedom micropositioner 10 further includes a sealed case 12. Both the inkjet printing device 11 and the six-degree-of-freedom motion platform 20 are located in the sealed case 12.

The sealed case 12 is provided with a return air inlet (not illustrated) and a return air outlet (not illustrated). A return air passage 121 communicating with the return air inlet and the return air outlet is arranged outside the sealed case 12. A fan unit 14 is arranged inside the sealed case 12, and configured to drive an air flow in the sealed case 12 to flow from the return air inlet to the return air outlet. A filter screen 15 and a flow-stabilizing plate 16 are sequentially arranged inside the sealed case 12 along a flow direction of gas in the sealed case 12. The six-degree-of-freedom motion platform 20 is located on a side of the flow-stabilizing plate 16 away from the filter screen 15.

In some embodiments, the fan unit 14 includes a plurality of fans 141, each of which is configured to drive the air flow in the sealed case 12 to flow from the return air inlet to the return air outlet. In other embodiments, the fan unit 14 may also include other driving devices capable of driving the flow of the gas as long as it enables the air flow in the sealed case 12 to flow from the return air inlet to the return air outlet.

The filter screen 15 can filter impurities in the gas. There are a plurality of ventilation holes on both the flow-stabilizing plate 16 and the filter screen 15. After passing through the filter screen 15 and flow-stabilizing plate 16 in sequence, the gas can be evenly distributed to a downstream space of the flow-stabilizing plate 16, so that the air flow in the environment of the six-degree-of-freedom motion platform 20 and the inkjet printing device 11 is stable. Disturbance of external environment to droplets is reduced, so that the droplets ejected by the inkjet head of the inkjet printing device 11 can accurately reach a target position on the to-be-processed substrate 30, thereby improving printing accuracy.

Furthermore, as shown in FIG. 1 and FIG. 2, the high-precision six-degree-of-freedom micropositioner 10 further includes a gas purifier 13 having an exhaust port communicating with the sealed case 12. The gas purifier 13 can provide purified gas to the sealed case 12, which ensures that sealed case 12 is in a stable pressure state on the one hand, and ensures that purity of the gas in the sealed case 12 is high on the other hand, thereby further improving the controllability of droplet ejection path in the sealed case 12 and improving the printing accuracy. When air pressure in the sealed case 12 decreases, the gas purifier 13 can inflate the sealed case 12, and when the air pressure in the sealed case 12 is too high, an exhaust valve on the sealed case 12 can be opened to exhaust.

After the to-be-processed substrate 30 is placed at the placement position 211, the six-degree-of-freedom motion platform 20 is adjusted so that a relative position between the to-be-processed substrate 30 and the inkjet head meets processing requirements, and then the inkjet head of the inkjet printing device 11 ejects solution onto the to-be-processed substrate 30. An entire inkjet process is carried out in the sealed case 12, and when the gas in the sealed case 12 flows under the drive of the fan unit 14, it needs to pass through the filter screen 15 and the flow-stabilizing plate 16 in sequence before being blown to the placement position 211. The air flow after passing through the filter screen 15 and the flow-stabilizing plate 16 is uniform and stable. In summary, the placement position 211 in the sealed case 12 is in a stable flow and pressure environment, which can reduce impact of the external environment on the disturbance of the droplets, so that the droplets ejected by the inkjet head can accurately reach the target position on the to-be-processed substrate 30, thereby improving the printing accuracy.

As shown in FIG. 2, in some embodiments, a periphery of the flow-stabilizing plate 16 is connected to the sealed case 12, and a space in the sealed case 12 is divided into an inkjet space layer 122 and an auxiliary space layer 123. The six-degree-of-freedom motion platform 20 and the inkjet printing device 11 are both located in the inkjet space layer 122. The filter screen 15 is located in the auxiliary space layer 123. The return air inlet is formed in a part of the sealed case 12 that encloses the auxiliary space layer 123, and the return air outlet is formed in a part of the sealed case 12 that encloses the inkjet space layer 122. In other words, uniform and stable air flow after passing through the filter screen 15 and the flow-stabilizing plate 16 enters the inkjet space layer 122. The inkjet printing device 11 and the six-degree-of-freedom motion platform 20 are both located in this uniform and stable air flow environment.

Further, in some embodiments, as shown in FIG. 2, the filter screen 15 is arranged in parallel with and spaced from the flow-stabilizing plate 16. The fan unit 14 includes a plurality of fans 141, and geometric centers of all fans 141 are evenly spaced apart on a virtual mounting plane. The virtual mounting plane is arranged in parallel with and spaced from the filter screen 15 and located on a side of the filter screen 15 away from the flow-stabilizing plate 16.

After the gas on an air inlet side is sucked in by the plurality of fans 141 arranged evenly at intervals, each of the plurality of fans 141 will blow out a portion of the gas. In this case, the gas is initially distributed, so that the uniformity of the air flow is improved. After the air flow blown out from the fan unit 14 further passes through the filter screen 15 and the flow-stabilizing plate 16, the uniformity is further improved, and the stability is high, so that the gas distribution in the inkjet space layer 122 is uniform and stable.

As shown in FIG. 1 and FIG. 2, in some embodiments, the high-precision six-degree-of-freedom micropositioner 10 includes a plurality of the return air passages 121, the sealed case 12 is provided with a plurality of pairs of the return air inlets and the return air outlets, and each pair of the return air inlet and the return air outlet corresponds to one of the plurality of return air passages 121. The use of the plurality of the return air passages 121 makes a return velocity of the air flow in each part of the sealed case 12 more consistent, air pressure of each part is more balanced, and the air flow is more stable.

As shown in FIG. 1 and FIG. 2, the sealed case 12 is a rectangular box, and the virtual mounting plane, the filter screen 15 and the flow-stabilizing plate 16 are all arranged parallel to a side of the rectangular box. The high-precision six-degree-of-freedom micropositioner 10 includes four return air passages 121, and the sealed case 12 is provided with four pairs of the return air inlet and the return air outlet, and one pair of the return air inlet and the return air outlet corresponds to one of the return air passages 121. Two of the return air passages 121 are located on a side of the rectangular box, and other two return air passages 121 are located on another side of the rectangular box. Two return air passages 121 located on the same side are spaced from each other in a direction perpendicular to an exhaust direction of the fan unit 14.

In an embodiment, as shown in FIG. 1 and FIG. 2, one of the sides of the rectangular box that is parallel to the virtual mounting plane is the top surface. Each return air inlet and each return air outlet are arranged on a lateral side of the rectangular box. Two of the return air passages 121 are located on a left side of the rectangular box, and other two return air passages 121 are located on a right side of the rectangular box. The return air passages 121 located on the same side are arranged at intervals in a front-to-back direction.

As shown in FIG. 1 and FIG. 2, in some embodiments, a position of the sealed case 12 where the sealed case 12 communicates with the gas purifier 13 is located on the air inlet side of the fan unit 14, and the purified gas output by the gas purifier 13 enters the air inlet side of the fan unit 14 and is sucked into the fan unit 14.

A position on the sealed case 12 where the return air inlet is formed is located on the air inlet side of the fan unit 14. The air flow from the return air inlet into the sealed case 12 is sucked by the fan unit 14 and then sent to the filter screen 15.

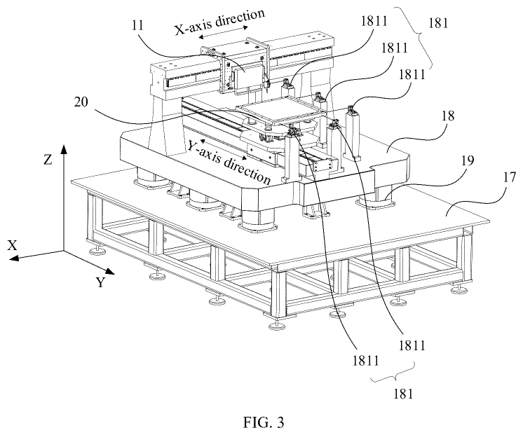

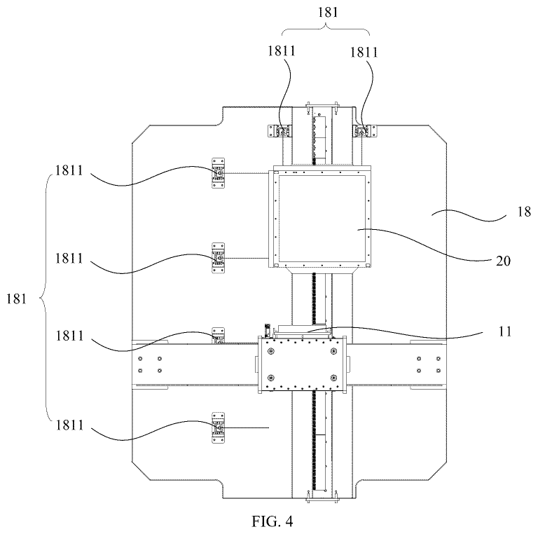

Furthermore, as shown in FIG. 3 and FIG. 4, in some embodiments, the high-precision six-degree-of-freedom micropositioner 10 includes a base 17 and a support platform 18, both of which are located in the sealed case 12. The supporting platform 18 is arranged on the base 17. The six-degree-of-freedom motion platform 20 is arranged on the supporting platform 18. The inkjet printing device 11 is arranged on the supporting platform 18. A shock-absorbing unit 19 is arranged between the supporting platform 18 and the base 17 to further reduce the influence of external vibration on an inkjet printing process.

In some embodiments, a relative position between a fixed part of the six-degree-of-freedom motion platform 20 and the inkjet printing device 11 is fixed. For example, the fixed part can be fixed on the supporting platform 18, and the placement position 211 belongs to a moving part of the six-degree-of-freedom motion platform 20. The six-degree-of-freedom motion platform 20 is configured to adjust the moving part to move in the X-direction, to move in the Y-direction, to move in the Z-direction, to rotate around the X-axis, to rotate around the Y-axis, or to rotate around the Z-axis relative to the fixed part. It can be understood that an initial position of the placement position 211 relative to the inkjet printing device 11 is fixed. When the to-be-processed substrate 30 is placed at the placement position 211, the inkjet head is already facing the to-be-processed substrate 30, and the to-be-processed substrate 30 only needs to be fine adjusted relative to the inkjet head.

In other embodiments, as shown in FIG. 3 and FIG. 4, the six-degree-of-freedom motion platform 20 is slidably arranged on the supporting platform 18. For example, the fixed portion of the six-degree-of-freedom motion platform 20 is slidably engaged with the supporting platform 18, and a direction in which the six-degree-of-freedom motion platform 20 can slide relative to the supporting platform 18 is the Y-direction.

The supporting platform 18 is provided with an X-axis guide rail spanning over a sliding path of the six-degree-of-freedom motion platform 20, and the inkjet printing device 11 can be slidably engaged on the X-axis guide rail.

In use, firstly, the six-degree-of-freedom motion platform 20 slides in the Y-direction relative to the supporting platform 18 as a whole. The inkjet printing device 11 slides in the X-direction relative to the supporting platform 18 until the inkjet head faces the to-be-processed substrate 30 placed at the placement position 211. In this case, the to-be-processed substrate 30 is initially positioned relative to the inkjet head. Then, an internal structure of the six-degree-of-freedom motion platform 20 moves, so that the placement position 211 moves relative to the fixed part of the six-degree-of-freedom motion platform 20, through which the to-be-processed substrate 30 is fine adjusted relative to the inkjet head. After initial positioning and fine adjustment, the relative position between the to-be-processed substrate 30 and the inkjet head meets inkjet requirements.

Further, as shown in FIG. 2 to FIG. 4, the six-degree-of-freedom motion platform 20 includes a six-degree-of-freedom adjustment unit and a substrate placement table 21. The placement position 211 is arranged on the substrate placement table 21, and the six-degree-of-freedom adjustment unit is configured to adjust the substrate placement table 21 relative to the inkjet head to move in the X-direction, to move in the Y-direction, to move in the Z-direction, to rotate around the X-axis, to rotate around the Y-axis, or to rotate around the Z-axis. The moving part of the six-degree-of-freedom motion platform 20 includes the substrate placement table 21.

The sealed case 12 further includes two position detection units 181 arranged therein. Each position detection unit 181 includes at least two laser probes 1811. Each laser probe 1811 is configured to emit laser toward the substrate placement table 21. The at least two laser probes 1811 of one of the two position detection units 181 are spaced sequentially along the X-direction, and the at least two laser probes 1811 of the other of the two position detection units 181 are spaced sequentially along the Y-direction.

The two position detection units 181 can detect whether the substrate placement table 21 moves to the target position, ensuring that the to-be-processed substrate 30 is finally accurately located at a desired position. The laser probes 1811 located in the sealed case 12 operates in a stable flow and pressure environment. Because the air flow is stable, probability of a slight deviation of the laser is low, and a clean gas environment in the sealed case 12 does not have impurities that affect a laser light path, which ultimately improves laser measurement accuracy.

In some embodiments, the six-degree-of-freedom adjustment unit is slidably arranged on the supporting platform 18, and the direction in which the six-degree-of-freedom adjustment unit can slide relative to the supporting platform 18 is the Y-direction. The supporting platform 18 is provided with an X-axis guide rail spanning over the sliding path of the six-degree-of-freedom adjustment unit, and the inkjet printing device 11 can be slidably engaged on the X-axis guide rail.

A reflector can be provided on a side of the substrate placement table 21 facing a respective laser probe 1811 to enhance reflection effect of the substrate placement table 21 on the laser.

In some embodiments of the present disclosure, a six-degree-of-freedom motion platform 20 is provided, which can be applied to the high-precision six-degree-of-freedom micropositioner 10 in any embodiment of the present disclosure, and can also be applied in other scenarios. In some of the embodiments, as shown in FIG. 6, the six-degree-of-freedom motion platform 20 includes a substrate placement table 21, an upper fine-adjustment layer 22, a middle mounting base 23, a lower fine-adjustment layer 24, and a bottom mounting base 25. The middle mounting base 23 is arranged between the substrate placement table 21 and the bottom mounting base 25 and spaced from the substrate placement table 21 and the bottom mounting base 25.

The lower fine-adjustment layer 24 acts between the bottom mounting base 25 and the middle mounting base 23 to adjust the middle mounting base 23 relative to the bottom mounting base 25, to move in the X-direction, to move in the Y-direction, or to rotate around the Z-axis.

The upper fine-adjustment layer 22 acts between the middle mounting base 23 and the substrate placement table 21 to adjust the substrate placement table 21 relative to the middle mounting base 23 to rotate around the X-axis, to rotate around the Y-axis, or to move in the Z-direction.

The placement position 211 is arranged on the substrate placement table 21, and the bottom mounting base 25 is arranged corresponding to the inkjet head, causing the inkjet head to eject solution onto the to-be-processed substrate 30 placed at the placement position 211.

In some embodiments, the six-degree-of-freedom adjustment unit includes an upper fine-adjustment layer 22, a middle mounting base 23, a lower fine-adjustment layer 24 and a bottom mounting base 25.

The upper fine-adjustment layer 22 and the lower fine-adjustment layer 24 are combined to enable the substrate placement table 21 to move in the X-direction, to move in the Y-direction, to move in the Z-direction, to rotate around the X-axis, to rotate around the Y-axis, or to rotate around the Z-axis relative to the bottom mounting base 25.

In some embodiments, the bottom mounting base 25 is arranged on the supporting platform 18. For example, the bottom mounting base 25 is fixedly connected, detachably connected, or slidably engaged with the supporting platform 18. In an embodiment, the bottom mounting base 25 is slidably arranged on the supporting platform 18, and a direction in which the bottom mounting base 25 can slide relative to the supporting platform 18 is the Y-direction.

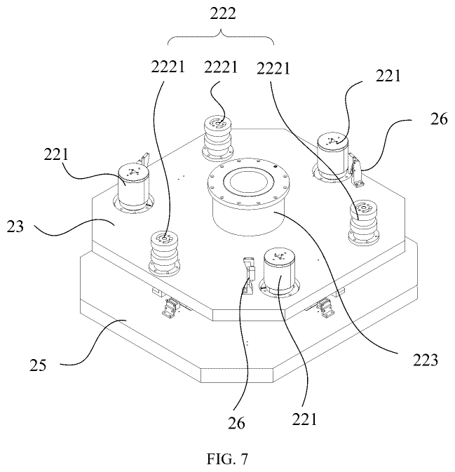

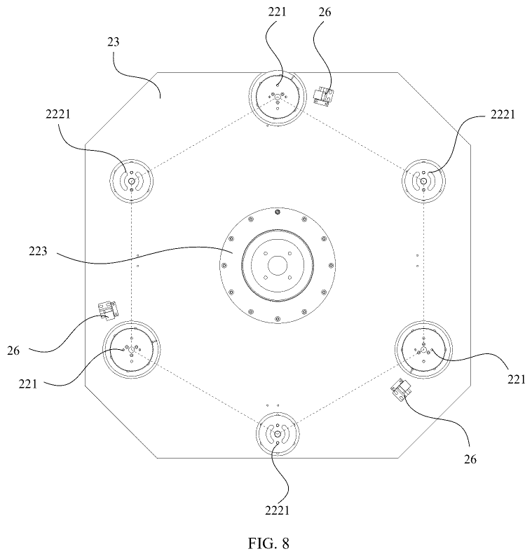

Furthermore, as shown in FIG. 7 and FIG. 8, in some embodiments, the upper fine-adjustment layer 22 includes a plurality of upper driving members 221 and a gravity balancing unit 222. All of the upper driving members 221 act between the middle mounting base 23 and the substrate placement table 21. Driving directions of all the upper driving members 221 are the Z-direction, and the gravity balancing unit 222 is supported between the middle mounting base 23 and the substrate placement table 21.

When the plurality of upper driving members 221 move synchronously, the substrate placement table 21 can be adjusted to move relative to the middle mounting base 23 in the Z-direction. When the plurality of upper driving members 221 move asynchronously, the substrate placement table 21 can be adjusted to rotate around the X-axis or around the Y-axis relative to the middle mounting base 23. The gravity balancing unit 222 is also supported between the middle mounting base 23 and the substrate placement table 21, sharing part of the gravity transmitted from the substrate placement table 21, reducing load of the upper driving member 221, and minimizing heat generated when the upper driving member 221 is in operation. In particular, when a large-sized panel such as an OLED substrate is placed at the placement position 211, the weight is relatively large. If it is fully supported by the upper driving member 221, the pressure that the upper driving member 221 needs to bear is relatively large, and a large amount of heat will be generated during the operation.

In the present disclosure, the gravity balancing unit 222 refers to a device that can automatically adjust external dimensions or automatically change parameters such as the magnetic force according to the distance between the substrate placement table 21 and the middle mounting base 23, to ensure that it can always provide support force for the substrate placement table 21 when the substrate placement table 21 is fine adjusted relative to the middle mounting base 23.

In some embodiments, as shown in FIG. 7 and FIG. 8, the gravity balancing unit 222 includes a plurality of gravity balancing airbags 2221. Each gravity balancing airbag is supported between the middle mounting base 23 and the substrate placement table 21. Optionally, the gravity balancing unit 222 may also be in other structural forms, as long as it can be supported between the middle mounting base 23 and the substrate placement table 21 and share part of the gravity transmitted from the substrate placement table 21.

Furthermore, in some embodiments, as shown in FIG. 8, a plurality of gravity balancing airbags 2221 and a plurality of upper driving members 221 are evenly spaced around the Z-axis, and at least one gravity balancing airbag 2221 is arranged between every two adjacent upper driving members 221 in the direction around the Z-axis, so as to ensure that the forces on each upper driving member 221 are balanced as much as possible.

In an embodiment, as shown in FIG. 8, the six-degree-of-freedom motion platform 20 includes three gravity balancing airbags 2221 and three upper driving members 221, and the three gravity balancing airbags 2221 and the three upper driving members 221 are respectively arranged at six corners of a hexagon.

As shown in FIG. 7 and FIG. 8, each upper driving member 221 is provided with a detection optical grating 26 configured to detect a motion distance of a mover of the corresponding upper driving member 221. The upper driving member 221 may include a voice coil motor.

Further, as shown in FIG. 7 and FIG. 8, in some embodiments, the upper driving member 221 includes a first voice coil motor. A coil of the first voice coil motor is connected to the middle mounting base 23. A magnet of the first voice coil motor is connected to the substrate placement table 21.

The upper fine-adjustment layer 22 further includes an air bearing 223. One of an air bearing shaft 2231 and a rotating ring 2232 of the air bearing 223 is connected to the substrate placement table 21, and the other of the air bearing shaft 2231 and the rotating ring 2232 is connected to the middle mounting base 23.

A main component that generates heat when the first voice coil motor is running is the coil, which is connected to the middle mounting base 23. The heat is mainly transferred to the middle mounting base 23. There is a gap between the air bearing shaft 2231 and the rotating ring 2232 of the air bearing 223, so less heat is transferred between the air bearing shaft 2231 and the rotating ring 2232, and the temperature of the substrate placement table 21 connected to the magnet is low, which prevents the substrate placement table 21 from being too high in temperature and transferring heat to the to-be-processed substrate 30 to affect the quality of the to-be-processed substrate 30. While supporting the substrate placement table 21, the heat transferred to the substrate placement table 21 is minimized.

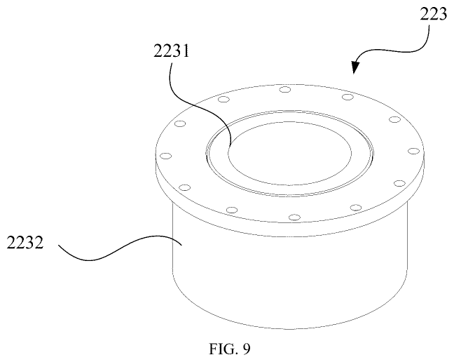

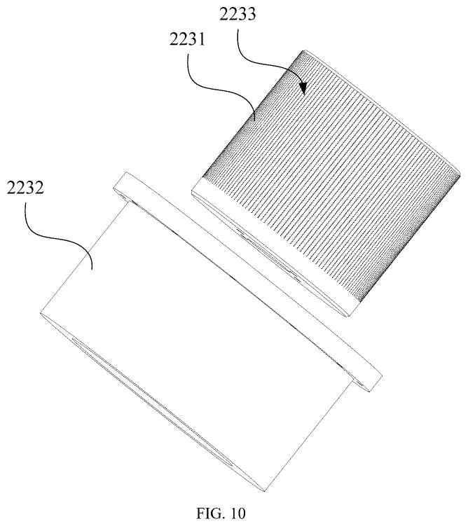

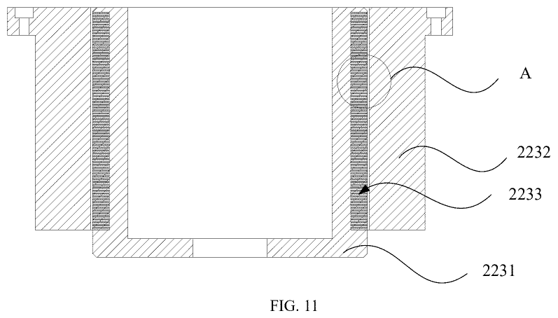

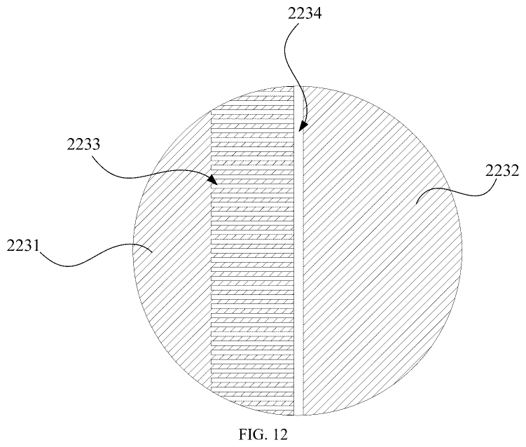

As shown in FIG. 9 to FIG. 12, the air bearing 223 includes an air bearing shaft 2231 and a rotating ring 2232. The air bearing shaft 2231 is inserted into the rotating ring 2232. A plurality of air holes 2233 are provided on an outer peripheral surface of the air bearing shaft 2231 facing the rotating ring 2232. When the air bearing shaft 2231 is ventilated, gas is discharged from the air holes 2233 on the air bearing shaft 2231, and an air film 2234 is formed between the air bearing shaft 2231 and the rotating ring 2232. An axial direction of the air bearing shaft 2231 is the Z-direction. The rotating ring 2232 can move along the Z-direction relative to the air bearing shaft 2231, and can also swing relative to the air bearing shaft 2231 and rotate around the X-axis or around the Y-axis.

As shown in FIG. 7 and FIG. 8, in some embodiments, the plurality of gravity balancing airbags 2221 and the plurality of upper driving members 221 are spaced apart around the air bearing 223.

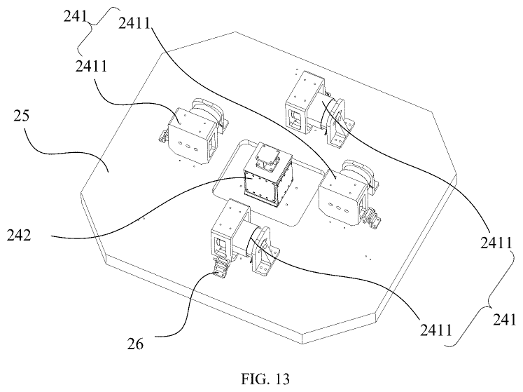

Furthermore, as shown in FIG. 13, in some embodiments, the lower fine-adjustment layer 24 includes a flexure spring 242 and two lower driving units 241. A driving direction of one of the two lower driving units 241 is the X-direction. A driving direction of the other of the two lower driving units 241 is the Y-direction. The two lower driving units 241 and the flexure spring 242 both act between the bottom mounting base 25 and the middle mounting base 23. The flexure spring 242 is deformable so as to move in the X-direction, move in the Y-direction, or rotate around the Z-axis.

Driven by the two lower driving units 241, the middle mounting base 23 can move in the X-direction, move in the Y-direction or rotate around the Z-axis relative to the bottom mounting base 25. The flexure spring 242 provides a guiding function for the middle mounting base 23, so that the middle mounting base 23 has higher movement accuracy when moving relative to the bottom mounting base 25.

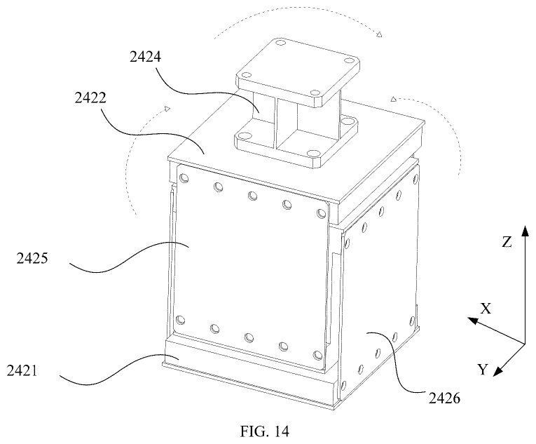

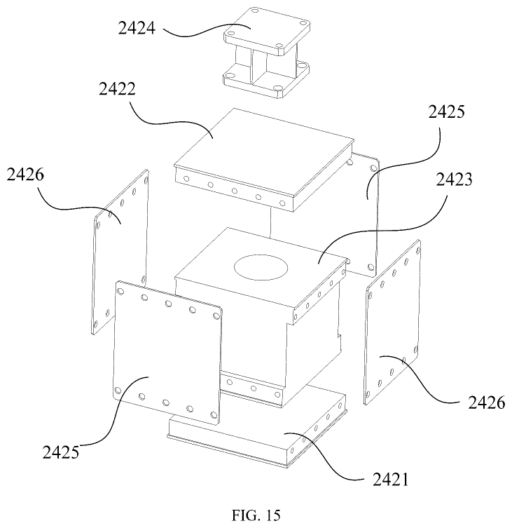

As shown in FIG. 14 and FIG. 15, in an embodiment, the flexure spring 242 includes a spring-mounting bottom base 2421, a spring-mounting top base 2422, a spring-mounting middle base 2423, a flexible-around-Z-axis spring leaf 2424, two first flexure spring leaf 2425, and two second flexure spring leaves 2426. The spring-mounting bottom base 2421 is mounted on the bottom mounting base 25. The flexible-around-Z-axis spring leaf 2424 is connected between the middle mounting base 23 and the spring-mounting top base 2422. The spring-mounting middle base 2423 is arranged between the spring-mounting bottom base 2421 and the spring-mounting top base 2422 and spaced from the spring-mounting bottom base 2421 and the spring-mounting top base 2422. Each first flexure spring leaf 2425 is connected between the spring-mounting top base 2422 and the spring-mounting middle base 2423. Each second flexure spring leaf 2426 is connected between the spring-mounting middle base 2423 and the spring-mounting bottom base 2421. The two first flexure spring leaves 2425 are arranged on opposite sides of the spring-mounting middle base 2423. The two second flexure spring leaves 2426 are arranged on further opposite sides of the spring-mounting middle base 2423.

When the two lower driving units 241 drive the middle mounting base 23 to make fine adjustment relative to the bottom mounting base 25, the flexible-around-Z-axis spring leaf 2424, the two first flexure spring leaves 2425 and the two second flexure spring leaves 2426 may be deformed, thereby adapting to relative displacement between the middle mounting base 23 and the bottom mounting base 25. As shown in FIG. 14, under the action of one of lower driving units 241, when the middle mounting base 23 moves relative to the bottom mounting base 25 in the Y-direction, the two first flexure spring leaves 2425 bend around the X-axis to produce elastic deformation, and two sides of the first flexure spring leaf 2425 connected to the spring-mounting top base 2422 and the spring-mounting middle base 2423 respectively deviate in the Y-direction, thereby adapting to the movement of the middle mounting base 23 relative to the bottom mounting base 25 in the Y-direction. Similarly, when the middle mounting base 23 moves in the X-direction relative to the bottom mounting base 25, the two second flexure spring leaves 2426 bend around the Y-axis to produce elastic deformation. Two sides of the second flexure spring leaves 2426 connected to the spring-mounting middle base 2423 and the spring-mounting bottom base 2421 respectively deviate in the X-direction, thereby adapting to the movement of the middle mounting base 23 relative to the bottom mounting base 25 in the X-direction. When the middle mounting base 23 rotates around the Z-axis relative to the bottom mounting base 25, the flexible-around-Z-axis spring leaf 2424 deforms, so that the middle mounting base 23 can rotate around the Z-axis relative to the spring-mounting top base 2422.

It should be noted that fine adjustment is performed based on the lower fine-adjustment layer 24, so the movement distance and movement angle of the middle mounting base 23 relative to the bottom mounting base 25 are relatively small. Therefore, the flexure spring leaves when each of them is offset in a certain direction, its shape or length may change slightly. This slight change can adapt to relative movement between the middle mounting base 23 and the bottom mounting base 25.

Optionally, the flexure spring 242 may also be in other structural forms, as long as it can move in the X-direction, move in the Y-direction and rotate around the Z-axis, and no specific limitation is made here.

As shown in FIG. 13, in some embodiments, each lower driving unit 241 includes two lower driving members 2411. Each of the two lower driving members 2411 of one of the two lower driving units 241 has a driving direction in the X-direction. Each of the two lower driving members 2411 of the other of the two lower driving units 241 has a driving direction in the Y-direction. Four lower driving members 2411 are evenly spaced around the flexure spring 242. The two lower driving members 2411 of one of the two lower driving units 241 are staggered with the two lower driving members 2411 of the other of the two lower driving units 241 in a direction around the flexure spring.

When the four lower driving members 2411 are all in operation, they can drive the middle mounting base 23 to rotate around the Z-axis relative to the bottom mounting base 25.

Moreover, in some embodiments, as shown in FIG. 13, each lower driving member 2411 is provided with a detection optical grating 26 configured to detect the motion distance of the mover of the corresponding lower driving member 2411.

The lower driving member 2411 may include a second voice coil motor.

In some other embodiments, the high-precision six-degree-of-freedom micropositioner 10 further includes a control unit. The detection optical gratings 26, the position detection units 181, the upper driving members 221 and the lower driving members 2411 can be electrically connected to the control unit to detect the position of the to-be-processed substrate 30 in real time and accurately control the six-degree-of-freedom motion platform 20 for fine adjustment.

In the description of the present disclosure, it should be understood that the terms “center”, “longitudinal”, “transverse”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and the like indicate orientations or positional relationships based on the orientations or positional relationships shown in the accompanying drawings, and are only for the convenience of describing the present disclosure and simplifying the description, and do not indicate or imply that the referred device or element must have a specific orientation, be constructed and operated in a specific orientation, and therefore should not be understood as a limitation on the present disclosure.

In addition, the terms “first” and “second” are used for descriptive purposes only and should not be understood as indicating or implying relative importance or implicitly indicating the number of the indicated technical features. Therefore, the features defined as “first” and “second” may explicitly or implicitly include at least one of the features. In the description of the present disclosure, the meaning of “plurality” is at least two, such as two, three, etc., unless otherwise clearly and specifically defined.

In the present disclosure, unless otherwise clearly specified and limited, the terms “installed”, “connected”, “connected”, “fixed” and the like should be understood in a broad sense, for example, it can be a fixed connection, a detachable connection, or an integral connection; it can be a mechanical connection or an electrical connection; it can be a direct connection or an indirect connection through an intermediate medium, it can be the internal connection of two elements or the interaction relationship between two elements, unless otherwise clearly defined. For a person of ordinary skill in the art, the specific meanings of the above terms in the present disclosure can be understood according to specific circumstances.

In the present disclosure, unless otherwise clearly specified and limited, a first feature being “above” or “below” a second feature may mean that the first and second features are in direct contact, or that the first and second features are in indirect contact through an intermediate medium. Moreover, a first feature being “above” a second feature may mean that the first feature is directly above or obliquely above the second feature, or simply means that the first feature is higher in level than the second feature. A first feature being “below” a second feature may mean that the first feature is directly below or obliquely below the second feature, or simply means that the first feature is lower in level than the second feature.

It should be noted that when an element is referred to as being “fixed to” or “arranged on” another element, it may be directly on the other element or there may be a central element. When an element is considered to be “connected to” another element, it may be directly connected to the other element or there may be a central element at the same time. The terms “vertical”, “horizontal”, “upper”, “lower”, “left”, “right” and similar expressions used herein are for illustrative purposes only and are not intended to be the only implementation method.

The technical features of the above-described embodiments may be arbitrarily combined. To make the description concise, not all possible combinations of the technical features in the above-described embodiments are described. However, as long as there is no contradiction in the combination of these technical features, they should be considered to be within the scope of this specification.

The above-described embodiments only express several implementation methods of the present disclosure, and the descriptions thereof are relatively specific and detailed, but they cannot be construed as limiting the scope of the patent application. It should be pointed out that, for a person of ordinary skill in the art, several variations and improvements can be made without departing from the concept of the present disclosure, and these all belong to the protection scope of the present disclosure. Therefore, the protection scope of the patent application shall be subject to the attached claims.

1. A high-precision six-degree-of-freedom micropositioner for fine adjustment of an OLED substrate, the high-precision six-degree-of-freedom micropositioner comprising:
an inkjet printing device;
a six-degree-of-freedom motion platform having a placement position for placing a to-be-processed substrate; and
a sealed case, the inkjet printing device and the six-degree-of-freedom motion platform being both located in the sealed case, an inkjet head of the inkjet printing device being configured to eject solution onto the to-be-processed substrate placed at the placement position, and the six-degree-of-freedom motion platform being configured to adjust a relative position between the placement position and the inkjet head,
wherein the sealed case is provided with a return air inlet and a return air outlet, a return air passage communicating with the return air inlet and the return air outlet is arranged outside the sealed case, a fan unit is arranged inside the sealed case, the fan unit is configured to drive air flow in the sealed case to flow from the return air inlet to the return air outlet, a filter screen and a flow-stabilizing plate are sequentially arranged inside the sealed case along a flow direction of gas in the sealed case, and the six-degree-of-freedom motion platform is located on a side of the flow-stabilizing plate away from the filter screen; and
a gas purifier having an exhaust port communicating with the sealed case.

2. The high-precision six-degree-of-freedom micropositioner of claim 1, wherein a periphery of the flow-stabilizing plate is connected to the sealed case, a space inside the sealed case is divided into an inkjet space layer and an auxiliary space layer, the six-degree-of-freedom motion platform and the inkjet printing device are both located in the inkjet space layer, the filter screen is located in the auxiliary space layer, the filter screen is arranged in parallel with and spaced from the flow-stabilizing plate, the fan unit comprises a plurality of fans, geometric centers of the plurality of fans are evenly spaced on a virtual mounting plane, the virtual mounting plane is arranged in parallel with and spaced from the filter screen and located on a side of the filter screen away from the flow-stabilizing plate, the return air inlet is formed in a part of the sealed case that encloses the auxiliary space layer, and the return air outlet is formed in a part of the sealed case that encloses the inkjet space layer.

3. The high-precision six-degree-of-freedom micropositioner of claim 1, wherein the high-precision six-degree-of-freedom micropositioner comprises a plurality of return air passages, the sealed case is provided with a plurality of pairs of the return air inlet and the return air outlet, and each pair of the return air inlet and the return air outlet corresponds to one of the plurality of return air passages.

4. The high-precision six-degree-of-freedom micropositioner of claim 1, wherein a position on the sealed case where the sealed case communicates with a gas purifier is located on an air inlet side of the fan unit; and
wherein a position on the sealed case where the return air inlet is formed is located on the air inlet side of the fan unit.

5. The high-precision six-degree-of-freedom micropositioner of claim 1, wherein the six-degree-of-freedom motion platform comprises a six-degree-of-freedom adjustment unit and a substrate placement table, the placement position is arranged on the substrate placement table, and the six-degree-of-freedom adjustment unit is configured to adjust the substrate placement table to move in an X-direction, to move in a Y-direction, to move in a Z-direction, to rotate around an X-axis, to rotate around a Y-axis, or to rotate around Z-axis relative to the inkjet head; and
wherein two position detection units are arranged inside the sealed case, each position detection unit comprises at least two laser probes, each laser probe is configured to emit laser toward the substrate placement table, the at least two laser probes of one of the two position detection units are spaced sequentially along the X-direction, and the at least two laser probes of the other of the two position detection units are spaced sequentially along the Y-direction.

6. The high-precision six-degree-of-freedom micropositioner of claim 1, wherein the six-degree-of-freedom motion platform comprises a substrate placement table, an upper fine-adjustment layer, a middle mounting base, a lower fine-adjustment layer and a bottom mounting base, the middle mounting base being arranged between the substrate placement table and the bottom mounting base and spaced from the substrate placement table and the bottom mounting base;
wherein the lower fine-adjustment layer acts between the bottom mounting base and the middle mounting base to adjust the middle mounting base to move in an X-direction, to move in a Y-direction, or to rotate around a Z-axis relative to the bottom mounting base;
wherein the upper fine-adjustment layer acts between the middle mounting base and the substrate placement table to adjust the substrate placement table to rotate around an X-axis, to rotate around a Y-axis, and to move in a Z-direction relative to the middle mounting base; and
whereat the placement position is arranged on the substrate placement table, and the bottom mounting base is arranged corresponding to the inkjet head, so that the inkjet head ejects solution onto the to-be-processed substrate placed at the placement position.

7. The high-precision six-degree-of-freedom micropositioner of claim 6, wherein the upper fine-adjustment layer comprises a plurality of upper driving members and a gravity balancing unit, all of the plurality of upper driving members act between the middle mounting base and the substrate placement table, and have driving directions in the Z-direction, and the gravity balancing unit is supported between the middle mounting base and the substrate placement table.

8. The high-precision six-degree-of-freedom micropositioner of claim 7, wherein the gravity balancing unit comprises a plurality of gravity balancing airbags, each gravity balancing airbag is supported between the middle mounting base and the substrate placement table, the plurality of gravity balancing airbags and the plurality of upper driving members are evenly spaced around the Z-axis, and at least one gravity balancing airbag is arranged between every two adjacent upper driving members in a direction around the Z-axis.

9. The high-precision six-degree-of-freedom micropositioner of claim 7, wherein the upper fine-adjustment layer further comprises an air bearing, the upper driving member comprising a first voice coil motor, a coil of the first voice coil motor being connected to the middle mounting base, a magnet of the first voice coil motor being connected to the substrate placement table, one of an air bearing shaft and a rotating ring of the air bearing being connected to the substrate placement table, and the other of the air bearing shaft and the rotating ring being connected to the middle mounting base; and
wherein each upper driving member is provided with a detection optical grating configured to detect a motion distance of a mover of the corresponding upper driving member.

10. The high-precision six-degree-of-freedom micropositioner of claim 6, wherein the lower fine-adjustment layer comprises a flexure spring and two lower driving units, one of the two lower driving units has a driving direction in the X-direction, the other of the two lower driving units has a driving direction in the Y-direction, the two lower driving units and the flexure spring both act between the bottom mounting base and the middle mounting base, and the flexure spring is deformable so as to move in the X-direction, move in the Y-direction, or rotate around the Z-axis.

11. The high-precision six-degree-of-freedom micropositioner of claim 10, wherein the flexure spring comprises a spring-mounting bottom base, a spring-mounting top base, a spring-mounting middle base, a flexible-around-Z-axis spring leaf, two first flexure spring leaves, and two second flexure spring leaves, the spring-mounting bottom base being mounted on the bottom mounting base, the flexible-around-Z-axis spring leaf being connected between the middle mounting base and the spring-mounting top base, the spring-mounting middle base being arranged between the spring-mounting bottom base and the spring-mounting top base and spaced from the spring-mounting bottom base and the spring-mounting top base, each first flexure spring leaf being connected between the spring-mounting top base and the spring-mounting middle base, each second flexure spring leaf being connected between the spring-mounting middle base and the spring-mounting bottom base, the two first flexure spring leaves being arranged on opposite sides of the spring-mounting middle base, and the two second flexure spring leaves being arranged on further opposite sides of the spring-mounting middle base.

12. The high-precision six-degree-of-freedom micropositioner of claim 10, wherein each lower driving unit comprises two lower driving members, each of the two lower driving members of one of the two lower driving units has a driving direction in the X-direction, each of the two lower driving members of the other of the two lower driving units has a driving direction in the Y-direction, four lower driving members are evenly spaced around the flexure spring, and the two lower driving members of one of the two lower driving units are staggered with the two lower driving members of the other of the two lower driving units in a direction around the flexure spring.

13. The high-precision six-degree-of-freedom micropositioner of claim 12, wherein each lower driving member is provided with a detection optical grating configured to detect a motion distance of a mover of the corresponding lower driving member; and
wherein the lower driving member comprises a second voice coil motor.

14. The high-precision six-degree-of-freedom micropositioner of claim 1, further comprising a base and a supporting platform, wherein both the base and the supporting platform are located in the sealed case, the supporting platform is arranged on the base, a shock-absorbing unit is arranged between the supporting platform and the base, the six-degree-of-freedom motion platform is arranged on the supporting platform, and the inkjet printing device is arranged on the supporting platform.

15. The high-precision six-degree-of-freedom micropositioner of claim 14, wherein the six-degree-of-freedom motion platform is slidably arranged on the supporting platform, and a direction in which the six-degree-of-freedom motion platform is slidable relative to the supporting platform is a Y-direction; and
the supporting platform is provided with an X-axis guide rail spanning over a sliding path of the six-degree-of-freedom motion platform, and the inkjet printing device is slidably engaged on the X-axis guide rail.

16. The high-precision six-degree-of-freedom micropositioner of claim 8, wherein the six-degree-of-freedom motion platform comprises three gravity balancing airbags and three upper driving members, the three gravity balancing airbags and the three upper driving members being respectively arranged at six corners of a hexagon.

17. The high-precision six-degree-of-freedom micropositioner of claim 9, wherein the air bearing shaft is inserted into the rotating ring, a plurality of air holes are provided on an outer peripheral surface of the air bearing shaft facing the rotating ring.

18. The high-precision six-degree-of-freedom micropositioner of claim 9, further comprising a control unit, the control unit being electrically connected to the detection optical grating, the upper driving members and the lower driving members to detect a position of the to-be-processed substrate in real time.

19. The high-precision six-degree-of-freedom micropositioner of claim 1, wherein both the flow-stabilizing plate and the filter screen are provided with a plurality of ventilation holes.

20. The high-precision six-degree-of-freedom micropositioner of claim 5, wherein a side of the substrate placement table facing a respective laser probe is provided with a reflector.
